(19) United States
(12) Patent Application Publication
(10) Pub. No.: US 2008/0061411 A1
(43) Pub. Date: Mar. 13, 2008

(54) Chip-stacked package structure for lead frame having bus bars with transfer pads

(75) Inventors: Geng-Shin Shen, Hsinchu (TW); Wu-Chang Tu, Hsinchu (TW)

Correspondence Address: REED SMITH LLP, Suite 1400, 3110 Fairview Park Drive, Falls Church, VA, 22042, US

(73) Assignees: Chipmos Technologies Inc.; Chipmos Technologies (Bermuda) Ltd.

(21) Appl. No.: 11/822,827

(22) Filed: Jul. 10, 2007

(30) Foreign Application Priority Data
Sep. 12, 2006 (TW) 095133663

(51) Int. Cl. H01L 23/495; H05K 7/18

(52) U.S. Cl. 257/670; 361/813; 257/E23.031

(57) ABSTRACT

A chip-stacked structure for packaging with lead-frame having bus bar formed with transfer pads is disclosed. The structure includes a lead-frame, an offset multi-chip-stacked structure, and an encapsulant. The lead frame includes a plurality of inner leads arranged in rows facing each other, a plurality of outer leads, and a die pad, the die pad being provided between the inner leads and being vertically distant from the inner leads. The offset multi-chip-stacked structure is set on the die pad and electrically connected with the inner leads. The encapsulant is used to cover the offset multi-chip-stacked structure and the lead frame. The lead frame also includes at least a bus bar provided between the inner leads and the die pad, and the bus bar is coated thereon with an insulation layer selectively formed with a plurality of metal pads.

### BACKGROUND OF THE INVENTION

This application incorporates by reference Taiwanese application Serial No. 95133663.

### FIELD OF THE INVENTION

This invention relates to a chip-stacked package structure used in multi-chip package and, more particularly, to an offset chip-stacked structure encapsulated with a lead-frame having bus bars with transfer pads on the bus bars for multi-chip package.

### DESCRIPTION OF THE RELATED ART

In semiconductor post-processing, many efforts have been made for increasing scale of the integrated circuits such as memories while minimizing the occupied area. Accordingly, the development of three-dimensional (3D) packaging technology is in progress and the idea of making up a chip-stacked structure has been disclosed.

The prior art has taught that a chip-stacked structure can be formed by firstly stacking a plurality of chips and then electrically connecting the chips to the substrate in a wire-bonding process. Referring to FIG. 1A, a conventional chip-stacked package structure 100 includes a substrate 110, chips 120a and 120b, a spacer 130, wires 140 and an encapsulant 150. The substrate 110 has many pads 112 on it and the chips 120a and 120b are also respectively provided with pads 122a and 122b arranged in peripheral type. The chip 120a is provided on the substrate 110, while the chip 120b is provided on the chip 120a with a spacer 130 intervened there-between. The chip 120a is electrically connected to the substrate 110 by bonding two ends of one of the wires 140 to the pads 112 and 122a respectively. The chip 120b is electrically connected to the substrate 110 in similar manner. The encapsulant 150 is then provided on the substrate 110 to cover the chips 120a and 120b and the wires 140.

Since the pads 122a and 122b are respectively provided at the peripheral of the chip 120a and the 120b, there is a need to apply the spacer 130 to prevent the chip 120b from directly contacting with the chip 120a for performing the subsequent wire-bonding. However, the use of spacer 130 increases the thickness of the chip-stacked package structure 100.

Another prior chip-stacked package structure for different-sized chips has been disclosed. Referring to FIG. 1B, another conventional chip-stacked package structure 10 includes a substrate 110, chips 120c and 120d, wires 140 and an encapsulant 150. The substrate 110 has pads 112 on it. The chip 120c is larger than the chip 120d in size. The chips 120c and 120d are respectively provided with peripherally arranged pads 122c and 122d. The chip 120c is provided on the substrate 110 while the chip 120d is provided on the chip 120c. The chip 120c is electrically connected to the substrate 110 by bonding two ends of one of the wires 140 to the pads 112 and 122c respectively. The chip 120d is electrically connected to the substrate 110 in similar manner. The encapsulant 150 is then provided on the substrate 110 to cover the chips 120c and 120d and the wires 140.

Since chip 120d is smaller than chip 120c, chip 120d would not cover the pads 122c of the chip 120c when the chip 120d is stacked on the chip 120c. However, the condition that the upper chip must have size smaller than that of the lower chip limits number of the chips to be stacked in the chip-stacked package structure 10.

In other words, the above-mentioned chip-stacked package structures have drawbacks of either increasing thickness or limiting number of the chips to be stacked. Moreover, there are also other problems that may lower reliability and yield of the chip-stacked structures during processing when wire-jumping or wire-crossing bonding of the chips is considered. For example, a high-pressured mold-flow injection during molding may cause the jumping or crossing wires to shift and become short.

### SUMMARY OF THE INVENTION

In view of the drawbacks and problems of the prior chip-stacked package structure as mentioned above, the present invention provides a new three-dimensional chip-stacked structure for packaging multi-chips with similar size.

One object of the present invention is to provide a chip-stacked package structure for lead frame having bus bar formed with transfer pads and so as to increase scale of the integrated circuits while reducing the thickness in a package.

Another object of the present invention is to provide an offset multi-chip-stacked structure for packaging with lead frame having bus bar formed with transfer pads and so as to make circuit design more flexible and gain higher reliability.

Accordingly, the present invention provides a chip-stacked package structure for lead frame having bus bar formed with transfer pads. The chip-stacked package structure includes a lead frame, an offset multi-chip-stacked structure, and an encapsulant. The lead frame comprises a plurality of inner leads arranged in rows facing each other, a plurality of outer leads, and a die pad provided between the inner leads and vertically distant from the inner leads. The offset multi-chip-stacked structure has a plurality of chips stacked, set on the die pad, and electrically connected with the inner leads. The encapsulant covers the offset multi-chip-stacked structure and the lead frame with the outer leads extending out of the encapsulant. The lead frame also includes at least one bus bar provided between the inner leads and the die pad and the bus bar is coated thereon with an insulation layer selectively formed with a plurality of metal pads.

The present invention also provides a chip-stacked package structure for lead frame having bus bar formed with transfer pads. The structure includes a lead frame, a plurality of offset multi-chip-stacked structures, and an encapsulant. The lead frame comprises a plurality of inner leads arranged in rows facing each other, a plurality of outer leads, and a die pad provided between the inner leads and vertically distant from the inner leads. The offset multi-chip-stacked structures each has a plurality of chips stacked, set on the die pad, and electrically connected with the inner leads. The encapsulant covers the offset multi-chip-stacked structures and the lead frame with the outer leads extending out of the encapsulant. The lead frame also includes at least one bus bar provided between the inner leads and the die pad and the bus bar is coated thereon with an insulation layer selectively formed with a plurality of metal pads.

The present invention also provides a lead frame structure having bus bar formed with transfer pads. The lead frame structure includes a plurality of inner leads arranged in rows facing each other, a die pad, and at least one bus bar, the die pad being provided between the inner leads and being vertically distant from the inner leads, the bus bar being provided between the inner leads and the die pad. The bus bar is coated thereon with an insulation layer selectively formed with a plurality of metal pads

### BRIEF DESCRIPTION OF THE DRAWINGS

The chip-stacked structure of this invention is illustrated in the drawing with like numerals indicating like parts. The brief description of the drawings is as follows.

FIG. 1A is a cross-sectional view schematically shows a conventional chip-stacked package structure for packaging multi-chips with same or similar size.

FIG. 1B is a cross-sectional view schematically shows a conventional chip-stacked package structure for packaging multi-chips with different size.

FIG. 2A is a top elevational view schematically shows the structure of chip according to the present invention.

FIG. 2B is a cross-sectional view schematically shows the structure of chip according to the present invention.

FIGS. 2C to 2E are cross-sectional views schematically show an offset chip-stacked structure for multi-chip package according to the present invention.

FIGS. 3A to 3C are top elevational views schematically show the redistribution layer formed in a process according to the present invention.

FIGS. 4A to 4B are cross-sectional views schematically show two portions of the bonding area on the redistribution layer according to the present invention.

FIGS. 5A to 5C are cross-sectional views schematically show three offset chip-stacked structures with redistribution layer according to the present invention.

FIGS. 6A to 6B are top elevational views schematically show two offset chip-stacked structures and connections between structures and lead frames according to the present invention.

FIGS. 7A to 7B are top elevational views schematically show another two offset chip-stacked structures and connections between structures and lead frames according to the present invention.

FIG. 8 is a cross-sectional view schematically shows an offset chip-stacked package structure for multi-chip package according to first embodiment of the invention.

FIG. 9 is a cross-sectional view schematically shows an offset chip-stacked package structure for multi-chip package according to second embodiment of the invention.

FIG. 10 is a cross-sectional view schematically shows an offset chip-stacked package structure for multi-chip package according to third embodiment of the invention.

FIG. 11 is a cross-sectional view schematically shows an offset chip-stacked package structure for multi-chip package according to fourth embodiment of the invention.

FIG. 12 is a cross-sectional view schematically shows an offset chip-stacked package structure for multi-chip package according to fifth embodiment of the invention.

FIG. 13 is cross-sectional view schematically shows an offset chip-stacked structure according to the present invention with offset occurring in another direction.

FIG. 14 is a cross-sectional view schematically shows an offset chip-stacked package structure for multi-chip package according to sixth embodiment of the invention.

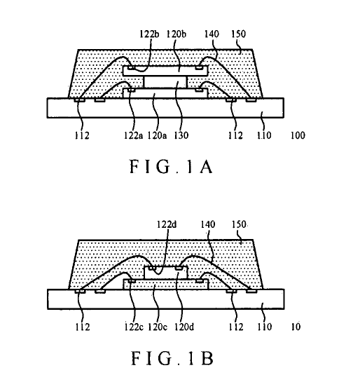

### DETAILED DESCRIPTION OF THE EMBODIMENTS

The present invention will now be described more fully hereinafter with reference to the accompanying drawings, in which preferred embodiments are shown. In the following, the well-known knowledge regarding the chip-stacked structure of the invention such as the formation of chip and the process of thinning the chip would not be described in detail to prevent from arising unnecessary interpretations. However, this invention will be embodied in many different forms and should not be construed as limited to the embodiments set forth herein.

According to the semiconductor packaging process, a Front-End-Process experienced wafer is firstly polished to reduce the thickness to a value between 2 mil and 20 mil, and then the polished wafer is applied with a polymer material such as a resin or a B-Staged resin by coating or printing. Next, a post-exposure baking or lighting process is applied to the polymer material so that the polymer material becomes a viscous semi-solidified gel-like material. Subsequently, a removable tape is attached to the viscous semi-solidified gel-like material and then the wafer is sawed into chips or dies. At last, these chips or dies are stacked on and connected to a substrate to form a chip-stacked structure.

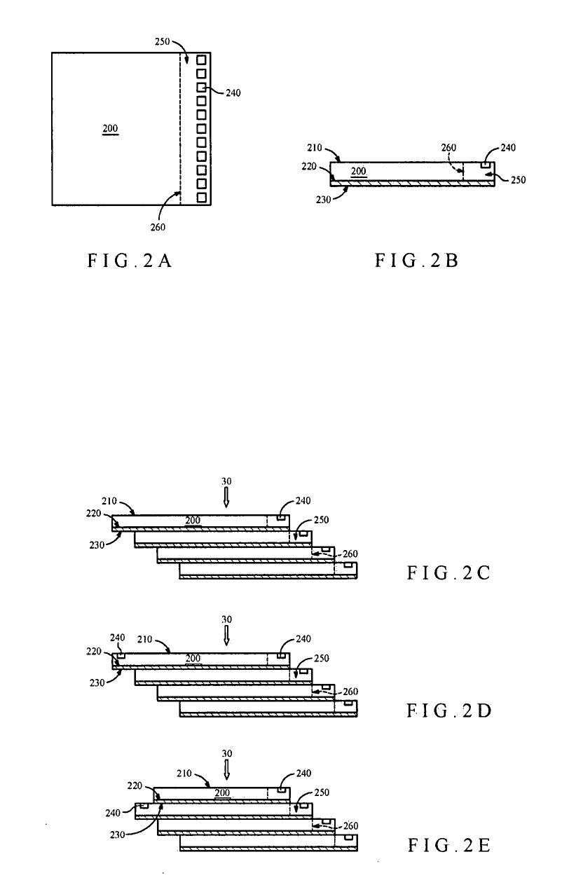

Referring to FIGS. 2A and 2B, a chip 200 experiencing the above-mentioned processes has an active surface 210 and a back surface 220 in opposition to the active surface 210 with an adhesive layer 230 formed on the back surface 220. It is to be noted that the adhesive layer 230 is not limited to the above-mentioned semi-solidified gel-like material and can be any adhesive material, such as die-attached film, for joining the chip 200 and a substrate together.

Moreover, the active surface 210 is thereon provided with a plurality of pads 240 arranged along a side edge. Accordingly, an offset multi-chip-stacked structure 30 as shown in FIG. 2C can be formed. The offset multi-chip-stacked structure 30 is a ladder-like structure formed by aligning the side edge of upper chips with the edge line 260 of the bonding area 250 on lower chips. The edge line 260 herein is a presumed line for reference only but not a line exists on chip 200.

Referring to FIG. 2D, the uppermost chip of the structure 30 can further have same pads as the pads 240 on the other side for providing more connections with the substrate. Referring to FIG. 2E, the uppermost chip of the structure 30 can have size smaller than that of the lower one. The arrangement of the pads 240 or the size of the chips described herein is for embodying but not limiting the invention. Any chip-stacked structure satisfying the above-mentioned statement would be regarded as an aspect of the invention.

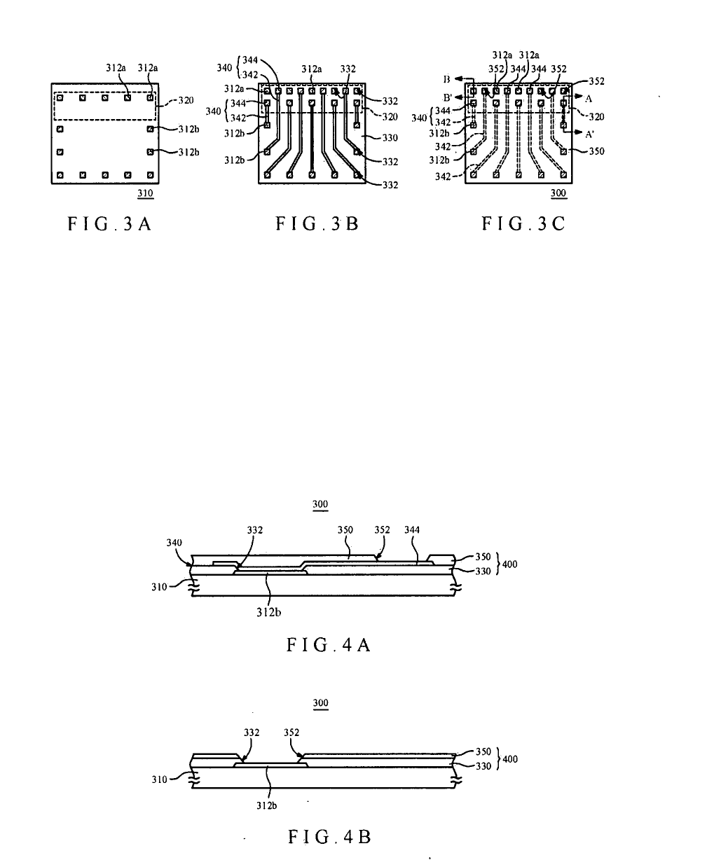

Referring to FIGS. 3A to 3C, the process of making a chip with redistribution layer is disclosed. According to the present invention, a redistribution layer (RDL) is formed with pads provided along a side edge of the chip and the details are described as follows.

As shown in FIG. 3A, the chip 310 has first pads 312a and second pads 312b on the active surface and along side edges. The first pads 312a are pads located inside a presumed bonding area 320, while the second pads 312b are pads located outside the presumed bonding area 320.

As shown in FIG. 3B, a first passivation layer 330 with a plurality first openings 332 for exposing the first pads 312a and the second pads 312b is first formed on the chip 310, and a redistribution layer 340 with a plurality of conductive wires 342 and a plurality of third pads 344 is then formed on the first passivation layer 33. The third pads 344 are located inside the presumed bonding area 320 and the conductive wires 342 electrically connects the second pads 312b and the third pads 344. The redistribution layer 340 is made up of conductive materials such as gold, copper, nickel, titanium tungsten, titanium or others.

As shown in FIG. 3C, a whole chip structure 300 is completed by forming a second passivation layer 350 with a plurality of second openings 352 on the redistribution layer 340 to cover the area rather than the first pads 312a and the third pads 344 but expose the first pads 312a and the third pads 344.

It is to be noted that the first pads 312a and the second pads 312b can be arranged on surface of the chip 310 riot only in the above-mentioned peripheral type but also in an area array type or other types rather than the above-mentioned types, provided that the second pads 312b are electrically connected with the third pads 344 via the conductive wires 342. Moreover, the third pads 344 can be arranged in a manner of being along side edge of the chip 310 and in parallel to the pads 312a such as shown in FIG. 3B or other manners provided that the third pads 344 are located inside the bonding area 320.

Referring now to FIGS. 4A and 4B, the A-A′ section and B-B′ section of whole chip structure 300 in FIG. 3C shows that the first pads 312a and the third pads 344 inside the bonding area 320 are exposed while the second pads 312b outside the bonding area 320 are covered. In this way, the area rather than the bonding area 320 on the second passivation layer 350 is capable of carrying another chip and therefore accomplishing an offset multi-chip-stacked structure 30.

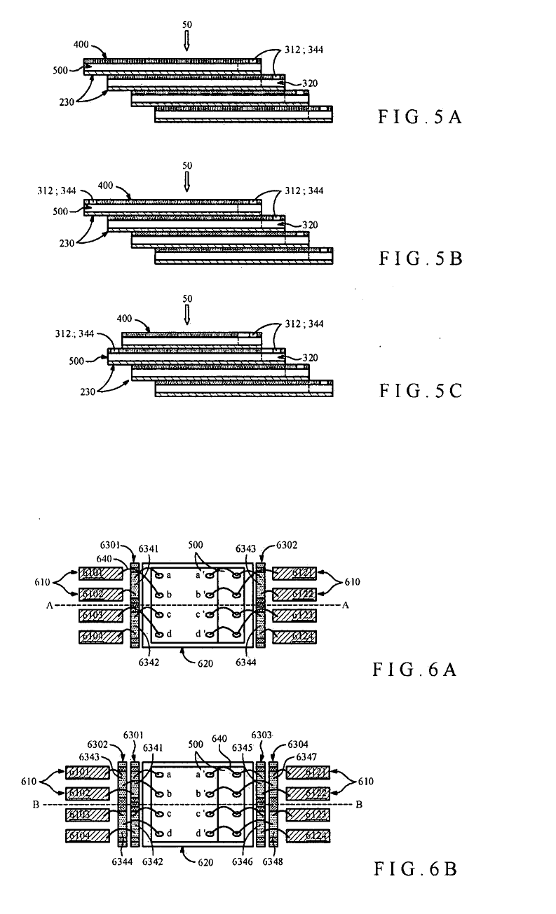

Referring to FIG. 5A, an offset chip-stacked structure 50 according to one embodiment of the invention includes a plurality of stacked chips 500. Each of the chips 500 is formed with a redistribution layer 400 so that each of the chips 500 can be provided with pads 312 and 344 only inside the bonding area 320 on each chip. In this way, the offset chip-stacked structure 50 is a ladder-like structure formed by aligning the side edge of upper chips with a presumed edge line of the bonding area 320 on lower chips and using a polymer material made adhesive layer 230 to connect any two chips. Referring to FIG. 5B, the uppermost chip of the structure 50 can further have same pads as the pads 312 and 344 on the other side for providing more connections with the substrate. Referring to FIG. 5C, the uppermost chip of the structure 50 can have size smaller than that of the lower one. The arrangement of the pads 312 and 344 or the size of the chips 500 described herein is for embodying but not limiting the invention. Any chip-stacked structure satisfying the above-mentioned statement would be regarded as an aspect of the invention. For example, each of the chips 500 can be formed with bonding areas that are not only on the right side as shown in FIGS. 5A to 5B but also on the left side.

In the following, two offset chip-stacked structures each connected with lead frames according to the present invention will be disclosed, in which the above-mentioned offset multi-chip-stacked structure 50 will be taken as an example for illustration. However, the following descriptions can also be applied to the above-mentioned offset multi-chip-stacked structure 30.

Referring to FIGS. 6A and 6B, a first offset chip-stacked package structure according to the present invention includes a lead frame 600 and an offset multi-chip-stacked structure 50. The lead frame 600 includes a plurality of inner leads 610 arranged in pairs, a plurality of outer leads (not shown) and a die pad 620 provided between the inner leads 610. Herein, the inner leads 610 and the die pad 620 are vertically at the same or different height. According to this embodiment, the offset multi-chip-stacked structure 50 is set on the die pad 620 and electrically connected to inner leads 610 of the lead frame 600 via the metal wires 640.

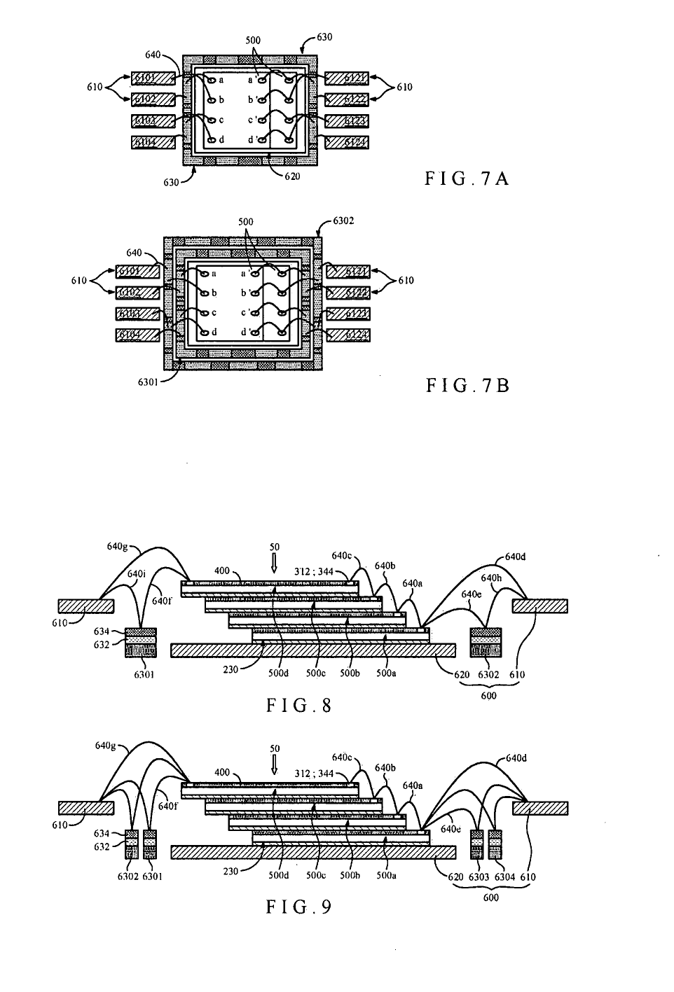

Furthermore, the lead frame 600 includes at least one bus bar 630 provided between the inner leads 610 and the die pad 620. The bus bar 630 can be configured to be strip shaped as shown in FIGS. 6A and 6B or be ring shaped as shown in FIGS. 7A and 7B. Moreover, the pads inside the bonding area of the chip 500 can be arranged in single row or two rows. Regarding the bus bar 630, there is further an insulation layer 632 on the surface and at least one metal pad 634 serving as transfer pad is formed on the insulation layer 632, which provides the lead frame 600 with more contacts for electrical connections such as ground connections or signal connections.

The insulation layer 632 is formed by coating or printing a polymer material such as polyimide (PI) or by attaching a tape such as die attached film. The metal pads 634 herein can be metal layers formed by plating process and etching process.

It is to be noted that the pads 634 can be selectively provided on the insulation layer 632 formed on the entire bus bar 630 or formed only on fragmental sections of the bus bar 630. Furthermore, another insulation layer formed on the metal pads 634 and other metal pads formed on this another insulation layer would be allowed for adding more transfer pads.

The description will go to the part of using the bas bar 630 to accomplish jumping connections of metal wires 640. Referring again to FIG. 6A, the pad with letter “a” (“a′”) and the pad with letter “c” (“c′”) on the chip 500 are connected to the inner lead 6102 (6122) and the inner lead 6104 (6124), respectively. Apparently, the metal pads 6341 and 6342 on the bus bar 6301 are respectively served as transferring pads for making jumping connections between the pad with letter “a” on the chip 500 and the inner lead 6102 and between the pad with letter “c” on the chip 500 and the inner lead 6104, while the metal pads 6343 and 6344 on the bus bar 6302 are respectively served as transferring pads for making jumping connections between the pad with letter “a′” on the chip 500 and the inner lead 6122 and between the pad with letter “c′” on the chip 500 and the inner lead 6124. In this way, the metal wires 640 would not cross each other.

For example, the pad with letter “a” on the chip 500 is connected to the metal pad 6341 on the bus bar 6301 with a metal wire 640, and the metal pad 6341 on the bus bar 6301 is connected to the inner lead 6102 with another metal wire 640. Therefore, the connection between the pad with letter “a” on the chip 500 and the inner lead 6102 can be made without crossing the metal wire 640 connecting the pad with letter “b” on the chip 500 and the inner lead 6101.

Also, the pad with letter “c” on the chip 500 is connected to the metal pad 6342 on the bus bar 6301 with a metal wire 640, and the metal pad 6342 on the bus bar 6301 is connected to the inner lead 6104 with another metal wire 640. Therefore, the connection between the pad with letter “c” on the chip 500 and the inner lead 6104 can be made without crossing the metal wire 640 connecting the pad with letter “d” on the chip 500 and the inner lead 6103. Similarly, the pads with letter “a′” and letter “c′” on the chip 500 are respectively connected to inner leads 6122 and 6124 by jumping metal wires 640 with metal pads 6343 and 6344 serving as transferring pads.

Referring to FIG. 6B, more than one bus bar 630 are provided when more of the pads on the chip 500 need jumping connection. Apparently, the metal pads 6341, 6342, 6343 and 6344 on the bus bars 6301 and 6302 are served as transferring pads for making jumping connections between the pad with letter “a” on the chip 500 and the inner lead 6102 and between the pad with letter “c” on the chip 500 and the inner lead 6104, while the metal pads 6345, 6346, 6347 and 6348 on the bus bars 6303 and 6304 are served as transferring pads for making jumping connections between the pad with letter “a′” on the chip 500 and the inner lead 6122 and between the pad with letter “c′” on the chip 500 and the inner lead 6124. In this way, the metal wires 640 would not cross each other.

For example, the pad with letter “a” on the chip 500 is connected to the metal pad 6341 on the bus bar 6301 with a metal wire 640, and the metal pad 6341 on the bus bar 6301 is connected to the inner lead 6102 with another metal wire 640. Similarly, pad with letter “b” on the chip 500 is connected to the metal pad 6343 on the bus bar 6302 with a metal wire 640, and the metal pad 6343 on the bus bar 6302 is connected to the inner lead 6101 with another metal wire 640. Therefore, the connection between the pad with letter “a” on the chip 500 and the inner lead 6102 can be made without crossing the metal wire 640 connecting the pad with letter “b” on the chip 500 and the inner lead 6101.

Similarly, the pad with letter “c” on the chip 500 is connected to the metal pad 6342 on the bus bar 6301 with a metal wire 640, and the metal pad 6341 on the bus bar 6301 is connected to the inner lead 6104 with another metal wire 640. Also, pad with letter “d” on the chip 500 is connected to the metal pad 6344 on the bus bar 6302 with a metal wire 640, and the metal pad 6344 on the bus bar 6302 is connected to the inner lead 6103 with another metal wire 640. Therefore, the connection between the pad with letter “c” on the chip 500 and the inner lead 6104 can be made without crossing the metal wire 640 connecting the pad with letter “d” on the chip 500 and the inner lead 6103.

The same wire jumping process is applied to connections of the pads with letter a′ to letter “d′” and the inner leads 6121 to 6124 without any wire-crossing.

Consequently, the bus bars 630 according to the present invention provides a plurality of transfer pads for jumping connections to prevent metal wires from crossing each other and avoid unnecessary short. Meanwhile, the bus bars 630 make the circuit design more flexible. For example, the jumping connection can be performed according to another type bus bar such as that shown in FIG. 7.

It is to be noted that the offset multi-chip-stacked structure 50 is set on the lead frame 600 and the chips 500 can be that having same size and performing same function such as memory chips or chips having different size and performing different function such as the case shown in FIGS. 2E and 5C. The detail description for size and function of these chips is omitted hereinafter.

Referring to FIG. 8, the lead frame 600 is connected with the offset chip-stacked structure 50 for multi-chip package via a plurality of metal wires 640. The lead frame 600 comprises a plurality of inner leads 610 arranged in two rows facing each other, a plurality of outer inner leads (not shown), a die pad 620, and a bus bar 630. The die pad 620 is provided between the inner leads 610 and is vertically distant from the inner leads 610. The bus bar 630 is provided between the inner leads 610 and the die pad 620. In this embodiment, the bus bar 630 and the die pad 620 are vertically at the same height.

The metal wire 640a has one end connected to the first pad 312a or third pad 344 of the chip 500a and has the other end connected to the first pad 312a or third pad 344 of the chip 500b in a wire-bonding process. Similarly, the metal wire 640b has one end connected to the first pad 312a or third pad 344 of the chip 500b and has the other end connected to the first pad 312a or third pad 344 of the chip 500c in a wire-bonding process. The metal wire 640c has one end connected to the first pad 312a or third pad 344 of the chip 500c and has the other end connected to the first pad 312a or third pad 344 of the chip 500d in a wire-bonding process. The metal wire 640d has one end connected to the first pad 312a or third pad 344 of the chip 500a and has the other end connected to the inner leads 610 in a wire-bonding process. In this way, the chips 500a, 500b, 500c and 500d are electrically connected to the lead frame 600 when the wire-bonding processes of the metal wires 640a, 640b, 640c, and 640d are completed. These metal wires 640a, 640b, 640c, and 640d can be gold made wires in one example.

Moreover, the bus bar 630 of the lead frame 600 is provided with metal pads 634 as transferring pads for electrical connections such as ground connections or signal connections. For example, the metal wire 640e has its one end connected to the first pad 312a or third pad 344 of the chip 500a and has its the other end selectively connected to the metal pads on the bus bar 6302, and the metal wire 640h has its one end connected to the metal pads on the bus bar 6302 and has it's the other end connected to one of the inner leads.

Moreover, the uppermost chip 500d of the structure 50 can further have same pads as the pads 312 and 344 on the other side such as the arrangement shown in FIGS. 2D and 5B. Therefore, a plurality of metal wires 640g are used to connect the chip 500d and the inner leads 610, while a metal wire 640f is used to connect the chip 500d and the bus bar 6301 and a metal wire 6401 is used to connect the bus bar 6301 and the inner leads 610. Specifically, the metal wire 640f has its one end connected to the first pad 312a or third pad 344 of the chip 500d and has its the other end selectively connected to the metal pads 634 on the bus bar 6301, and the metal wire 6401 has its one end connected to the metal pads 634 on the bus bar 6301 and has it's the other end connected to one of the inner leads 610.

The insulation layers 632 on the bus bar 630 and the metal pads 634 on the insulation layers 632 make the connection of the pads on the structure 50 more flexible. For example, some of the metal pads 634 are used for ground connection while other metal pads 634 are used for power connection or for signal connection. Therefore, when wire-jumping is needed for the electrical connection of the pads on the structure 50, the connection can be completed via metal pads 634 without making the wires cross one another. This prevents the metal wires from increasing bending degrees and enables flexibility in the circuit design or application and thus raises the yield and reliability in package processing.

It is to be noted that the chip 500b is stacked on and adhered to the area outside the bonding area 320 of the chip 500a via a polymer material made adhesive layer 230 such as the arrangement shown in FIGS. 5A to 5C. However, the wire-bonding sequence of the metal wires 640 is not limited herein, which means it is also allowable to first bond the uppermost chip 500d and finally bond the lowermost chip 500a and then connect the chip 500a with the lead frame 600.

Referring to FIG. 9, a plurality of bus bars 630 are provided herein and these bus bars 630 are configured to be strip shaped as shown in FIG. 6B or be ring shaped as shown in FIG. 7B. Each of the bus bars 630 in this embodiment is provided with at least one insulation layer 632 and a plurality of metal pads 634 on the insulation layer 632. Apparently, increasing the number of the bus bars and therefore the number of transfer pads makes the connection of the pads on the structure 50 more flexible so that some of the metal pads 634 are used for ground connection while others of the metal pads 634 are used for power connection or for signal connection. Therefore, when wire-jumping is needed for the electrical connection of the pads on the structure 50, the connection can be completed via metal pads 634 without making the wires cross one another. This prevents the metal wires from increasing bending degrees and enables flexibility in the circuit design or application and thus raises the yield and reliability in package processing. The process of using the metal wires 640 for connection between the lead frame 600 and the structure 50 is similar to that as described with reference to FIG. 6B and FIG. 8 and would not be given unnecessary details herein.

Referring to FIG. 10, a plurality of wires 640 are used to connect the lead frame 600 with the offset chip-stacked structure 50. The lead frame 600 comprises a plurality of inner leads 610 arranged in two rows facing each other, a plurality of outer inner leads (not shown), a die pad 620, and a bus bar 630. The die pad 620 is provided between the inner leads 610 and is vertically distant from the inner leads 610. The bus bar 630 is provided between the inner leads 610 and the die pad 620. In this embodiment, the bus bar 630 and the inner leads 610 are vertically at the same height. Each of the bus bars 630 is provided with at least one insulation layer 632 and a plurality of metal pads 634 on the insulation layer. The structure 50 is first connected to and then wire-bonded to the lead frame 600. The process of wire-bonding the structure 50 to the lead frame 60 is similar to that as described with reference to FIG. 8 and FIG. 9 and would not be given unnecessary details herein. Moreover, the bus bar 630 of the lead frame 600 is provided with metal pads 634 as transferring pads for electrical connections such as ground connections or signal connections. Each of the metal wire 640 has its one end connected to the first pad 312a or third pad 344 of one of the chips and has its the other end selectively connected to the metal pads on the bus bar 630. It is to be noted that the strip shape or ring shape and the number of the bus bars 630 here are examples only but not limit the structure and the number of bus bar 630 when different circuit designs are considered.

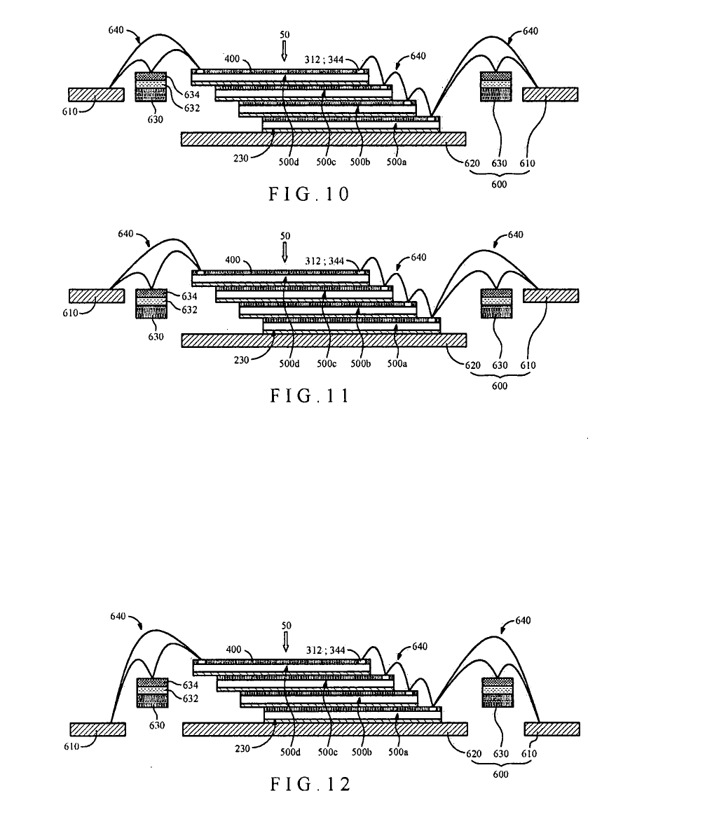

Referring now to FIG. 11, a plurality of wires 640 are used to connect the lead frame 600 with the offset chip-stacked structure 50. The lead frame 600 comprises a plurality of inner leads 610 arranged in two rows facing each other, a plurality of outer inner leads (not shown), a die pad 620, and a bus bar 630. The die pad 620 is provided between the inner leads 610 and is vertically distant from the inner leads 610. The bus bar 630 of strip shape or ring shape is provided between the inner leads 610 and the die pad 620. Apparently, the lead frame 600 and the structure 50 shown herein are similar to that shown in FIG. 8 and FIG. 10 except that the bus bars 630 and the inner leads 610 are vertically at different height and the bus bars 630 and the die pad 620 are vertically at different height also. Each of the bus bars 630 is provided with at least one insulation layer 632 and a plurality of metal pads 634 on the insulation layer. The process of wire-bonding the structure 50 to the lead frame 60 is similar to that as described with reference to FIG. 8 and FIG. 9 and would not be given unnecessary details herein. Moreover, the bus bar 630 of the lead frame 600 is provided with metal pads 634 as transferring pads for electrical connections such as ground connections or signal connections. Each of the metal wire 640 has its one end connected to the first pad 312a or third pad 344 of one of the chips and has its the other end selectively connected to the metal pads on the bus bar 630. It is to be noted that the strip shape or ring shape and the number of the bus bars 630 here are examples only but not limit the structure and the number of bus bar 630 when different circuit designs are considered.

Referring now to FIG. 12, a plurality of wires 640 are used to connect the lead frame 600 with the offset chip-stacked structure 50. The lead frame 600 comprises a plurality of inner leads 610 arranged in two rows facing each other, a plurality of outer inner leads (not shown), a die pad 620, and a bus bar 630. The die pad 620 is provided between the inner leads 610 and is vertically distant from the inner leads 610. The bus bar 630 of strip shape or ring shape is provided between the inner leads 610 and the die pad 620. Apparently, the lead frame 600 and the structure 50 shown herein are similar to that shown in FIGS. 8, 10, and 11 except that the bus bars 630 and the inner leads 610 are vertically at different height and the bus bars 630 and the die pad 620 are vertically at different height also. Each of the bus bars 630 is provided with at least one insulation layer 632 and a plurality of metal pads 634 on the insulation layer. The process of wire-bonding the structure 50 to the lead frame 60 is similar to that as described with reference to FIG. 8 and FIG. 9 and would not be given unnecessary details herein. Moreover, the bus bar 630 of the lead frame 600 is provided with metal pads 634 as transferring pads for electrical connections such as ground connections or signal connections. Each of the metal wire 640 has its one end connected to the first pad 312a or third pad 344 of one of the chips and has its the other end selectively connected to the metal pads on the bus bar 630. It is to be noted that the strip shape or ring shape and the number of the bus bars 630 here are examples only but not limit the structure and the number of bus bar 630 when different circuit designs are considered.

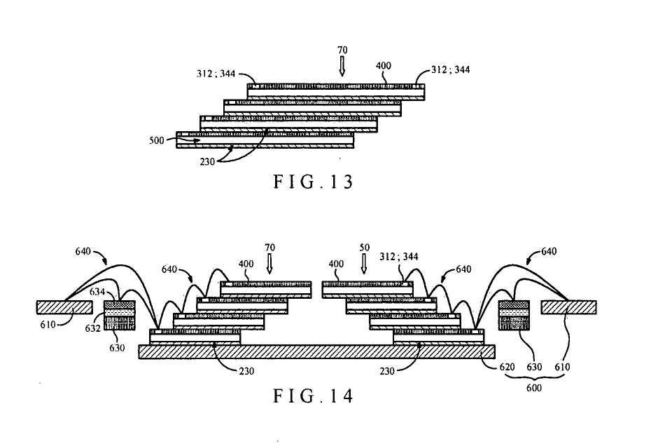

As described in the above embodiments, the number of the chips of the chip-stacked structure 50 is not so limited, and any person skilled in the art could manufacture a chip-stacked structure including three chips according to the above-disclosed method. Meanwhile, the direction toward which the offset of each chip occurs in forming the structure 50 is not so limited by the above-disclosed embodiments. The chip-stacked structure can be formed with each chip having an offset toward the direction opposite to the original one disclosed in the above embodiments, such as the chip-stacked structure 70 shown in FIG. 13. Referring to FIG. 13, the connection method for the chips of the structure 70 and the wire-bonding method for the chips and the lead frame are similar to that disclosed in the above-mentioned embodiments and would not be given unnecessary details herein.

Moreover, the present invention proposed a combination structure in which two offset chip-stacked structure with chips of each structure being offset toward opposite directions are combined together. An example of such is shown in FIG. 14. Referring to FIG. 14, the structures 50 and 70 are provided together on a die pad 620 of a lead frame 600. The connection method for the chips of the structures 70 and 50 and the wire-bonding method for the chips and the lead frame are similar to that disclosed in the above-mentioned embodiments and would not be given unnecessary details herein. Each bus bar 630 is provided with at least one insulation layer 632 and a plurality of metal pads 634 on the insulation layer. The process of wire-bonding the structures 50 and 70 to the lead frame 60 is similar to that as described with reference to FIG. 8 and FIG. 9 and is not be given unnecessary details herein. Moreover, the bus bar 630 of the lead frame 600 is provided with metal pads 634 as transferring pads for electrical connections such as ground connections or signal connections. Each of the metal wire 640 has its one end connected to the first pad 312a or third pad 344 of one of the chips and has its the other end selectively connected to the metal pads on the bus bar 630. It is to be noted that the strip shape or ring shape and the number of the bus bars 630 here are examples only but not limit the structure and the number of bus bar 630 when different circuit designs are considered.

While the invention has been described by way of examples and in terms of the preferred embodiments, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A chip-stacked package structure for lead frame having bus bar formed with transfer pads, comprising:
a lead frame comprising a plurality of inner leads arranged in rows facing each other, a plurality of outer leads, and a die pad, the die pad being provided between the inner leads and being vertically distant from the inner leads;
an offset multi-chip-stacked structure with a plurality of chips stacked, the offset multi-chip-stacked structure being set on the die pad and electrically connected with the inner leads;
an encapsulant covering the offset multi-chip-stacked structure and the lead frame with the outer leads extending out of the encapsulant; and
at least one bus bar provided between the inner leads and the die pad, the bus bar coated thereon with an insulation layer selectively formed with a plurality of metal pads.

2. The chip-stacked package structure as set forth in claim 1, wherein the bus bar and the die pad being vertically at the same height.

3. The chip-stacked package structure as set forth in claim 1, wherein the bus bar and the inner leads being vertically at the same height.

4. The chip-stacked package structure as set forth in claim 1, wherein the bus bar, the inner leads, and the die pad being vertically at different height.

5. The chip-stacked package structure as set forth in claim 1, wherein another insulation layer selectively formed with a plurality of other metal pads being coated on the metal pads.

6. The chip-stacked package structure as set forth in claim 1, wherein the bus bar being arranged in a ring-shaped configuration.

7. The chip-stacked package structure as set forth in claim 1, wherein the bus bar being arranged in a stripe-shaped configuration.

8. The chip-stacked package structure as set forth in claim 1, wherein the chips of the offset multi-chip-stacked structure each comprising:
a body having a bonding area located close to one side edge of the body, a plurality of first pads being formed inside the bonding area and a plurality of second pads being formed outside the bonding area;
a first passivation layer provided on the body with a plurality of first openings formed on the first passivation layer to expose the first pads and the second pads;
a redistribution layer formed with a plurality of third pads inside the bonding area is provided on the first passivation layer for establishing connection between the second pads and the bonding area; and
a second passivation layer provided to cover the redistribution layer with a plurality of second openings formed on the second passivation layer to expose the first pads and the third pads.

9. A chip-stacked package structure for lead frame formed with transfer pads, comprising:
a lead frame comprising a plurality of inner leads arranged in rows facing each other, a plurality of outer leads, and a die pad, the die pad being provided between the inner leads and being vertically distant from the inner leads;
a plurality of offset multi-chip-stacked structures each has a plurality of chips stacked, the offset multi-chip-stacked structure being set on the die pad and electrically connected with the inner leads; and
an encapsulant covering the offset multi-chip-stacked structure and the lead frame with the outer leads extending out of the encapsulant;
wherein the lead frame comprising at least one bus bar provided between the inner leads and the die pad, the bus bar coated thereon with an insulation layer selectively formed with a plurality of metal pads.

10. The chip-stacked package structure as set forth in claim 9, wherein the bus bar and the die pad being vertically at the same height.

11. The chip-stacked package structure as set forth in claim 9, wherein the bus bar and the inner leads being vertically at the same height.

12. The chip-stacked package structure as set forth in claim 9, wherein the bus bar, the inner leads, and the die pad being vertically at different height.

13. A lead frame structure having bus bar formed with transfer pads, comprising a plurality of inner leads arranged in rows facing each other, a die pad, and at least one bus bar, the die pad being provided between the inner leads and being vertically distant from the inner leads, the bus bar being provided between the inner leads and the die pad, the lead frame structure is characterized in that:
the bus bar is coated thereon with an insulation layer selectively formed with a plurality of metal pads.

14. The lead frame structure as set forth in claim 13, wherein the bus bar and the die pad being vertically at the same height.

15. The lead frame structure as set forth in claim 13, wherein the bus bar and the inner leads being vertically at the same height.

16. The lead frame structure as set forth in claim 13, wherein the bus bar, the inner leads, and the die pad being vertically at different height.

17. The lead frame structure as set forth in claim 13, wherein the insulation layer on the bus bar is selected from the group consisting of a polyimide and a die attached film.

18. The lead frame structure as set forth in claim 13, wherein the metal pads on the bus bar being formed by a processing selected from the group consisting of electrical plating and etching.

19. The lead frame structure as set forth in claim 13, wherein the bus bar being arranged in a ring-shaped configuration.

20. The lead frame structure as set forth in claim 13, wherein the bus bar being arranged in a stripe-shaped configuration.
